(19) United States
(12) Patent Application Publication
(10) Pub. No.: US 2025/0382700 A1
(43) Pub. Date: Dec. 18, 2025

(54) SUBSTRATE PROCESSING METHOD, SUBSTRATE PROCESSING SYSTEM, AND PROTECTIVE FILM

(71) Applicant: Tokyo Electron Limited, Tokyo (JP)

(72) Inventors: Junya SUZUKI, Nirasaki City (JP); Masahisa WATANABE, Nirasaki City (JP)

(21) Appl. No.: 19/302,533

(22) Filed: Aug. 18, 2025

Related U.S. Application Data
(63) Continuation of application No. PCT/JP2024/005214, filed on Feb. 15, 2024.

(30) Foreign Application Priority Data
Feb. 22, 2023 (JP) 2023-026021

(51) Int. Cl. C23C 16/40; C23C 16/02; C23C 16/455

(52) U.S. Cl. CPC C23C 16/404; C23C 16/0236; C23C 16/45553

(57) ABSTRACT

A substrate processing method includes preparing a substrate having a base film formed thereon; forming a protective film on the base film, performing a dry etching process on the substrate in which a stacked structure of the base film and the protective film is formed, and removing the protective film from the substrate in which the stacked structure of the base film and the protective film is formed. The forming the protective film on the base film includes forming an MgO film as the protective film by repeating supplying an organometallic gas containing magnesium (Mg) to the substrate and supplying an oxidizing agent to the substrate at a film formation temperature of 250 degrees C. or lower.

### CROSS-REFERENCE TO RELATED APPLICATIONS

This application is a bypass continuation application of International Application No. PCT/JP2024/005214 having an international filing date of Feb. 15, 2024 and designating the United States, the international application being based upon and claiming the benefit of priority from Japanese Patent Application No. 2023-026021, filed on Feb. 22, 2023, the entire contents of which are incorporated herein by reference.

### TECHNICAL FIELD

The present disclosure relates to a substrate processing method, a substrate processing system, and a protective film.

### BACKGROUND

Patent Document 1 discloses a method of converting a metal oxide layer into a metal hydride layer by exposing the metal oxide layer to a reactive hydrogen-containing gas or plasma, and sublimating the metal hydride layer by heating the metal hydride layer to at least a sublimation temperature.

### PRIOR ART DOCUMENT

### Patent Document

Patent Document 1: Japanese Laid-Open Patent Publication No. 2020-535657

### SUMMARY

According to one embodiment of the present disclosure, a substrate processing method includes preparing a substrate having a base film formed thereon, forming a protective film on the base film, performing a dry etching process on the substrate in which a stacked structure of the base film and the protective film is formed, and removing the protective film from the substrate in which the stacked structure of the base film and the protective film is formed, wherein the forming the protective film on the base film includes forming an MgO film as the protective film by repeating supplying an organometallic gas containing magnesium (Mg) to the substrate and supplying an oxidizing agent to the substrate at a film formation temperature of 250 degrees C. or lower.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating an example of a configuration of a substrate processing system.

FIG. 2 is a flowchart illustrating an example of a substrate processing method.

FIG. 3A is an example of a schematic cross-sectional diagram of a substrate in each operation.

FIG. 3B is an example of the schematic cross-sectional diagram of the substrate in each operation.

FIG. 3C is an example of the schematic cross-sectional diagram of the substrate in each operation.

FIG. 4 is a schematic diagram illustrating an example of a substrate processing apparatus.

FIG. 5 is a flowchart illustrating an example of a film formation processing of the substrate processing apparatus.

FIG. 6 is a graph illustrating an example of a film thickness before and after a dry etching process and after a DIW process.

FIG. 7 is an example of a graph illustrating a relationship between a film formation temperature and a growth per cycle (GPC) of an MgO film.

FIG. 8 is an example of a graph illustrating a relationship between the film formation temperature and a density of the MgO film.

FIG. 9 is an example of a graph illustrating a relationship between the film formation temperature and a film composition of the MgO film.

FIG. 10 is an example of a graph illustrating a relationship between the film formation temperature and a film thickness of the MgO film.

### DETAILED DESCRIPTION

Hereinafter, embodiments for implementing the present disclosure will be described with reference to the drawings. In each drawing, there may be a case where the same components are designated by like reference numerals with the duplicate descriptions thereof omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### [Substrate Processing System]

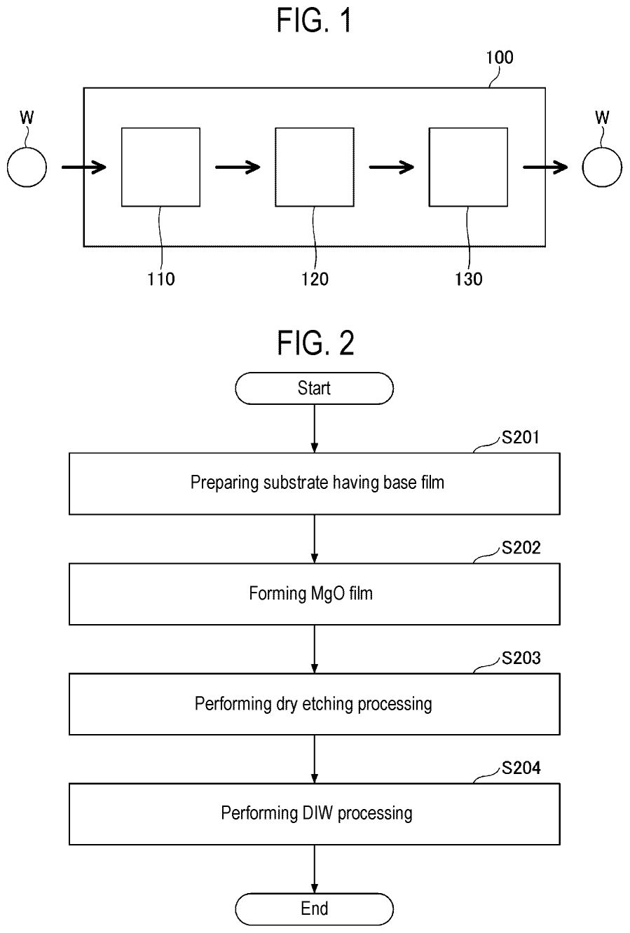

A substrate processing system 100 according to the present embodiment will be described with reference to FIG. 1. FIG. 1 is a diagram illustrating an example of a configuration of the substrate processing system 100.

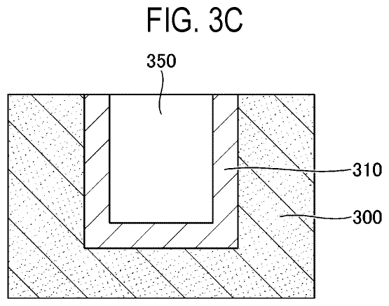

The substrate processing system 100 is a substrate processing system that forms a protective film 320 (see FIG. 3B) for protecting a base film 310 (see FIGS. 3A to 3C) when a dry etching process is performed on a substrate W having the base film 310 formed thereon. In addition, the substrate processing system 100 is a substrate processing system that removes the protective film 320 from the substrate W after performing the dry etching process on the substrate W.

The substrate processing system 100 includes a film formation apparatus (substrate processing apparatus) 110, a dry etching apparatus 120, and a protective film removal apparatus 130. A space between the film formation apparatus 110 and the dry etching apparatus 120 may be configured such that the substrate W is transferred in an air atmosphere or may be configured such that the substrate W is transferred in a vacuum atmosphere.

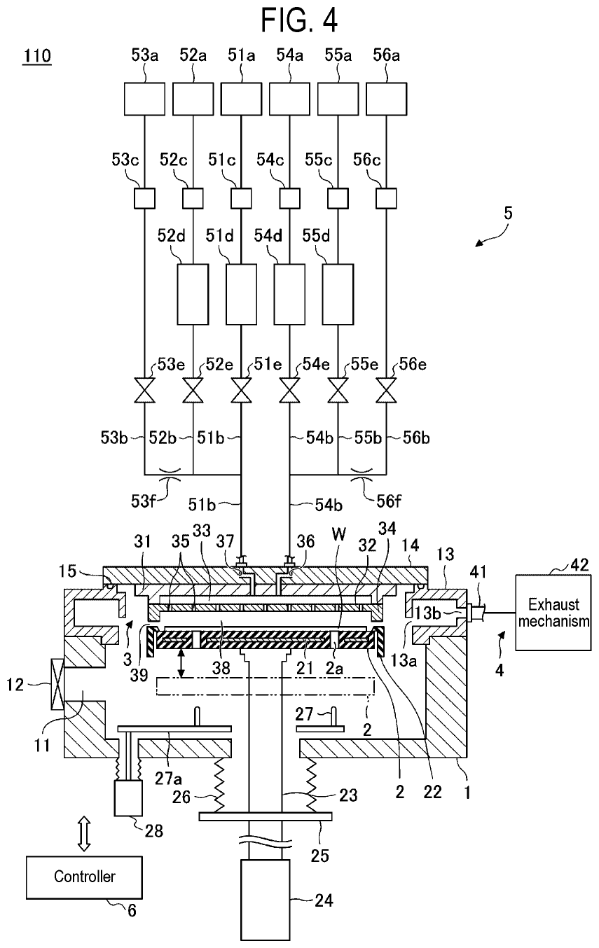

The film formation apparatus 110 is a film formation apparatus that forms the protective film 320 (see FIG. 3B), which will be described later, on the substrate W. As the protective film 320, for example, an MgO film is formed. In addition, the film formation apparatus 110 may be an atomic layer deposition (ALD) apparatus. Details of the film formation apparatus 110 will be described later with reference to FIG. 4. The film formation apparatus 110 is not limited to the ALD apparatus and may also be a chemical vapor deposition (CVD) apparatus.

The dry etching apparatus 120 is an apparatus that performs the dry etching process on the substrate W. The dry etching apparatus 120 etches, for example, SiO₂ formed on the substrate W. In addition, the dry etching apparatus 120 may be a parallel plate type plasma etching apparatus. The parallel plate type plasma etching apparatus generates capacitively coupled plasma (CCP). In addition, the plasma etching apparatus is a dry etching apparatus that uses, for example, a CF-based gas (gas containing carbon (C) and fluorine (F)) as an etching gas and causes ions to collide with the substrate W in a vertical direction to perform etching in the vertical direction (anisotropic etching). The CF-based gas may be, for example, a C₄F₈ gas, a CF₄ gas, or the like. In addition to the CF-based gas, an O₂ gas may be added as the etching gas. An Ar gas or a N₂ gas may also be added as the etching gas.

The protective film 320 has etching resistance to the dry etching process and protects the base film 310 during the dry etching process.

The protective film removal apparatus 130 is an apparatus that removes the protective film 320 formed on the substrate W. The protective film removal apparatus 130 is a cleaning apparatus that supplies pure water (deionized water (DIW)) to the substrate W to clean the substrate W.

Here, the protective film 320 exhibits solubility in water (the pure water). The protective film removal apparatus 130 removes the protective film 320 formed on the substrate W by performing the pure water cleaning process on the substrate W and dissolving the protective film 320 in water.

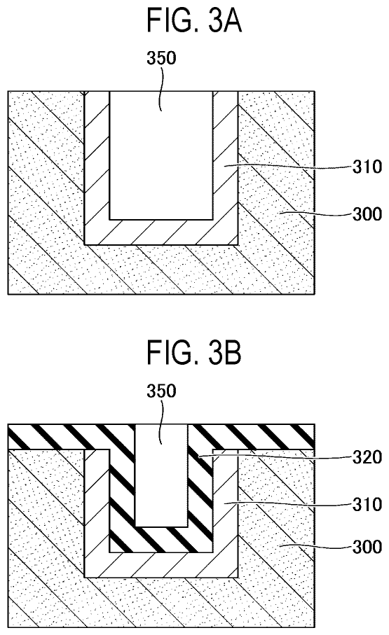

Next, an example of a substrate processing method using the substrate processing system 100 will be described with reference to FIG. 2 and FIGS. 3A to 3C. FIG. 2 is a flowchart illustrating an example of the substrate processing method. FIGS. 3A to 3C are examples of schematic cross-sectional diagrams of the substrate W in each operation.

In Operation S201, the substrate W having the base film 310 formed thereon is prepared.

An example of the prepared substrate W will now be described with reference to FIG. 3A. FIG. 3A is an example of a schematic cross-sectional diagram of the substrate W prepared in Operation S201. A concave portion 350 having a trench shape or the like has been formed on a surface of a layer 300 of the substrate W. Further, the base film 310 has been formed on an inner wall and bottom surface of the concave portion 350. The base film 310 is not limited to being formed on the inner wall and bottom surface of the concave portion 350. In addition, a film type of the base film 310 is not limited.

In Operation S202, the protective film 320 is formed on the substrate W. Here, the protective film 320 is formed on the base film 310 of the substrate W by the film formation apparatus 110. As a result, a stacked structure of the base film 310 and the protective film 320 is formed on the substrate W. In addition, the protective film 320 is a film that has dry etching resistance and may be etched away by water. The protective film 320 is an MgO film.

An example of the substrate W on which the protective film 320 is formed will be described with reference to FIG. 3B. FIG. 3B is an example of a schematic cross-sectional diagram of the substrate W on which the protective film 320 is formed in Operation S202. The protective film 320 is formed on the layer 300 and the base film 310 and covers the layer 300 and the base film 310.

Here, the film formation apparatus 110 that forms the protective film 320 (MgO film) on the substrate W will now be described with reference to FIG. 4. FIG. 4 is a schematic diagram illustrating an example of the film formation apparatus 110.

The film formation apparatus 110 includes a processing container 1, a stage 2, a shower head 3, an exhauster 4, a gas supply 5, and a controller 6.

The processing container 1 is made of a metal such as aluminum and has a substantially cylindrical shape. The processing container 1 accommodates the substrate W. A loading/unloading port 11 for loading or unloading the substrate W therethrough is formed in a sidewall of the processing container 1. The loading/unloading port 11 is open and closed by a gate valve 12. An annular exhaust duct 13 having a rectangular cross section is provided on a main body of the processing container 1. A slit 13a is formed along an inner peripheral surface of the exhaust duct 13. An exhaust port 13b is formed in an outer wall of the exhaust duct 13. A ceiling wall 14 is provided on an upper surface of the exhaust duct 13 to close an upper opening of the processing container 1. A space between the exhaust duct 13 and the ceiling wall 14 is air-tightly sealed with a seal ring 15.

The stage 2 horizontally supports the substrate W inside the processing container 1. The stage 2 has a disc shape larger than the substrate W and is made of a ceramic material such as aluminum nitride (AlN) or a metal material such as an aluminum or a nickel alloy. A heater 21 for heating the substrate W is embedded in the stage 2. The heater 21 is supplied with power from a heater power source (not shown) to generate heat. Then, an output of the heater 21 is adjusted based on a temperature signal from a thermocouple (not shown) provided near an upper surface of the stage 2 so that the substrate W is adjusted to a predetermined temperature. The stage 2 is provided with a cover member 22 made of ceramics such as alumina to cover an outer peripheral area of the upper surface of the stage 2 and a side surface of the stage 2.

The stage 2 is supported by a support member 23. The support member 23 extends downward from the center of a bottom surface of the stage 2 by passing through a hole formed in a bottom wall of the processing container 1 and a lower end thereof is connected to a lifting mechanism 24. The stage 2 is raised and lowered by the lifting mechanism 24 between a processing position indicated by a solid line in FIG. 4 and a transfer position at which the substrate W may be transferred, indicated by a dash-double-dotted line below the processing position. A flange portion 25 is attached to the support member 23 below the processing container 1. A bellows 26 is provided between a bottom surface of the processing container 1 and the flange portion 25. The bellows 26 isolates an internal atmosphere of the processing container 1 from ambient air and is flexible with the vertical movement of the stage 2.

Three wafer support pins 27 (only two of which are shown) are provided near the bottom surface of the processing container 1 to protrude upward from a lifting plate 27a. The wafer support pins 27 are raised and lowered via the lifting plate 27a by a lifting mechanism 28 provided below the processing container 1. The wafer support pins 27 are inserted into through-holes 2a provided in the stage 2 located at the transfer position so as to be movable upward and downward with respect to the upper surface of the stage 2. By raising and lowering the wafer support pins 27, the substrate W is delivered between a transfer robot (not shown) and the stage 2.

The shower head 3 supplies a processing gas into the processing container 1 in the form of a shower. The shower head 3 is made of, for example, a metal material and is arranged to face the stage 2. The shower head 3 has almost the same diameter as the stage 2. The shower head 3 includes a main body 31 and a shower plate 32. The main body 31 is fixed to a lower surface of the ceiling wall 14. The shower plate 32 is connected to a lower portion of the main body 31. A gas diffusion space 33 is formed between the main body 31 and the shower plate 32. In the gas diffusion space 33, gas introduction holes 36 and 37 are provided so as to penetrate the center of the ceiling wall 14 and the main body 31. An annular protrusion 34 protruding downward is formed at a peripheral portion of the shower plate 32. A plurality of gas discharge holes 35 is formed in an inner flat surface of the annular protrusion 34 of the shower plate 32.

When the stage 2 is located at the processing position, a processing space 38 is formed between the stage 2 and the shower plate 32. An upper surface of the cover member 22 and the annular protrusion 34 are close to each other to form an annular gap 39.

The exhauster 4 exhausts an interior of the processing container 1. The exhauster 4 includes an exhaust pipe 41 and an exhaust mechanism 42. The exhaust pipe 41 is connected to the exhaust port 13b. The exhaust mechanism 42 is connected to the exhaust pipe 41 and includes a vacuum pump, a pressure control valve, and the like. The exhaust mechanism 42 exhausts gas in the processing container 1 via the exhaust duct 13 and the exhaust pipe 41.

The gas supply 5 supplies various gases to the shower head 3. The gas supply 5 includes a raw material gas source 51a, a purge gas source 52a, a carrier gas source 53a, an oxygen-containing gas source 54a, a purge gas source 55a, and a carrier gas source 56a.

The raw material gas source 51a supplies a raw material gas into the processing container 1 via a gas supply line 51b. A flow controller 51c, a storage tank 51d, and a valve 51e are installed in the gas supply line 51b from an upstream side. A downstream side of the valve 51e of the gas supply line 51b is connected to the gas introduction hole 37. The raw material gas supplied from the raw material gas source 51a is temporarily stored in the storage tank 51d before being supplied into the processing container 1, and then is supplied into the processing container 1 after being pressurized to a predetermined pressure in the storage tank 51d. The supply and cutoff of the raw material gas from the storage tank 51d to the processing container 1 are performed by the valve 51e. By temporarily storing the raw material gas in the storage tank 51d in this way, the raw material gas may be supplied into the processing container 1 at a relatively high flow rate in a short period of time.

The purge gas source 52a supplies a purge gas into the processing container 1 via a gas supply line 52b. A flow controller 52c, a storage tank 52d, and a valve 52e are installed in the gas supply line 52b from an upstream side. A downstream side of the valve 52e of the gas supply line 52b is connected to the gas supply line 51b. The purge gas supplied from the purge gas source 51a is temporarily stored in the storage tank 52d before being supplied into the processing container 1, and then is supplied into the processing container 1 after being pressurized to a predetermined pressure in the storage tank 52d. The supply and cutoff of the purge gas from the storage tank 52d to the processing container 1 are performed by the valve 52e. By temporarily storing the purge gas in the storage tank 51d in this way, the purge gas may be supplied into the processing container 1 at a relatively high flow rate in a short period of time.

The carrier gas source 53a supplies a carrier gas into the processing container 1 via a gas supply line 53b. A flow controller 53c, a valve 53e, and an orifice 53f are installed in the gas supply line 53b from an upstream side. A downstream side of the orifice 53f of the gas supply line 53b is connected to the gas supply line 51b. The carrier gas supplied from the carrier gas source 53a is continuously supplied into the processing container 1 while film formation is performed on the substrate W. The supply and cutoff of the carrier gas from the carrier gas source 53a to the processing container 1 are performed by the valve 53e. The orifice 53f suppresses a relatively large flow of gas, which is supplied to the gas supply lines 51b and 52b by the storage tanks 51d and 52d, from flowing backward through the gas supply line 53b.

The oxygen-containing gas source 54a supplies an oxygen-containing gas into the processing container 1 via a gas supply line 54b. A flow controller 54c, a storage tank 54d, and a valve 54e are installed in the gas supply line 54b from an upstream side. A downstream side of the valve 54e of the gas supply line 54b is connected to the gas introduction hole 36. The oxygen-containing gas supplied from the oxygen-containing gas source 54a is temporarily stored in the storage tank 54d before being supplied into the processing container 1, and then is supplied into the processing container 1 after being pressurized to a predetermined pressure in the storage tank 54d. The supply and cutoff of the oxygen-containing gas from the storage tank 54d to the processing container 1 are performed by the valve 54e. By temporarily storing the oxygen-containing gas in the storage tank 54d in this way, the oxygen-containing gas may be supplied into the processing container 1 at a relatively high flow rate in a short period of time.

The purge gas source 55a supplies the purge gas into the processing container 1 via a gas supply line 55b. A flow controller 55c, a storage tank 55d, and a valve 55e are installed in the gas supply line 55b from an upstream side. A downstream side of the valve 55e of the gas supply line 55b is connected to the gas supply line 54b. The purge gas supplied from the purge gas source 55a is temporarily stored in the storage tank 55d before being supplied into the processing container 1, and then is supplied into the processing container 1 after being pressurized to a predetermined pressure in the storage tank 55d. The supply and cutoff of the purge gas from the storage tank 55d to the processing container 1 are performed by the valve 55e. By temporarily storing the purge gas in the storage tank 54d in this way, the purge gas may be supplied into the processing container 1 at a relatively high flow rate in a short period of time.

The carrier gas source 56a supplies the carrier gas into the processing container 1 via a gas supply line 56b. A flow controller 56c, a valve 56e, and an orifice 56f are installed in the gas supply line 56b from an upstream side. A downstream side of the orifice 56f of the gas supply line 56b is connected to the gas supply line 54b. The carrier gas supplied from the carrier gas source 56a is continuously supplied into the processing container 1 while film formation is performed on the substrate W. The supply and cutoff of the carrier gas from the carrier gas source 56a to the processing container 1 are performed by the valve 56e. The orifice 56f suppresses a relatively large flow of gas, which is supplied to the gas supply lines 54b and 55b by the storage tanks 54d and 55d, from flowing backward through the gas supply line 56b.

Here, the raw material gas is an organometallic gas containing at least magnesium (Mg). Specifically, the raw material gas may use any one selected from a group consisting of:

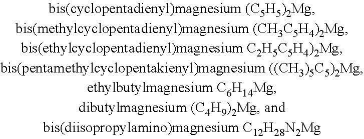

The oxygen-containing gas is an O₃ gas. Alternatively, the oxygen-containing gas may be a mixed gas of an O₂ gas and the O₃ gas (the O₃ gas to which the O₂ gas is added). In addition, the oxygen-containing gas is an example of an oxidizing agent that oxidizes the organometallic gas containing magnesium (Mg) adsorbed onto the substrate W.

The purge gas and the carrier gas may use, for example, an inert gas such as a N₂ gas or an Ar gas.

The controller 6 is, for example, a computer, and includes, for example, a central processing unit (CPU), a random access memory (RAM), a read only memory (ROM), and an auxiliary storage device. The CPU operates based on a computer readable program stored in the ROM or the auxiliary storage device, and controls operations of the film formation apparatus 110. The controller 6 may be provided either inside or outside the film formation apparatus 110. In the case in which the controller 6 is provided outside the film formation apparatus 110, the controller 6 may control the film formation apparatus 110 via a wired or wireless communication network.

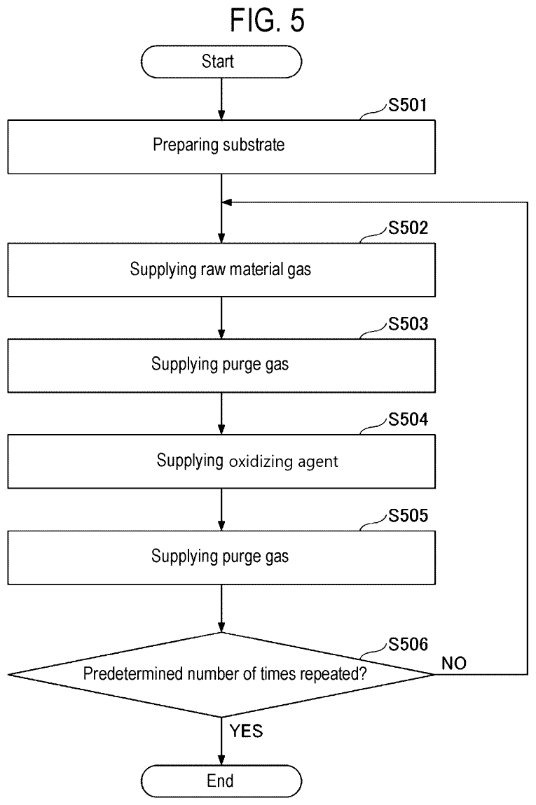

Next, an example of film formation processing of the film formation apparatus 110 will be described with reference to FIG. 5. FIG. 5 is a flowchart illustrating an example of the film formation processing of the film formation apparatus 110.

In Operation S501, the substrate W is prepared. Here, the base film 310 has been formed on the substrate W as illustrated in FIG. 3A.

First, in a state in which the valves 51e to 56e are closed, the gate valve 12 is open to transfer the substrate W into the processing container 1 by the transfer robot (not shown), and the substrate W is loaded on the stage 2 located at the transfer position. After the transfer robot is withdrawn from the processing container 1, the gate valve 12 is closed. The substrate W is heated to a predetermined film formation temperature (e.g., 250 degrees C. or lower) by the heater 21 of the stage 2. The stage 2 is raised to the processing position to form the processing space 38. In addition, the interior of the processing container 1 is adjusted to have a predetermined pressure by the pressure control valve of the exhaust mechanism 42.

Next, the valves 53e and 56e are open to supply the carrier gas of a predetermined flow rate from the carrier gas sources 53a and 56a to the gas supply lines 53b and 56b, respectively. In addition, the raw material gas, the purge gas, the oxygen-containing gas, and the purge gas are supplied from the raw material gas source 51a, the purge gas source 52a, the oxygen-containing gas source 54a, and the purge gas source 55a to the gas supply lines 51b, 52b, 54b, and 55b, respectively. In this case, since the valves 51e, 52e, 54e, and 55e remain closed, the raw material gas, the purge gas, the oxygen-containing gas, and the purge gas are stored in the storage tanks 51d, 52d, 54d, and 55d, respectively, so that interiors of the storage tanks 51d, 52d, 54d, and 55d are pressurized.

In Operation S502, the raw material gas is supplied to the processing space 38 in which the substrate W is placed. The controller 6 performs control to open the valve 51e. After a predetermined period of time has elapsed, the controller 6 performs control to close the valve 51e. As a result, the raw material gas stored in the storage tank 51d is supplied into the processing space 38 of the processing container 1 so that the raw material gas is adsorbed onto the substrate W.

In Operation S503, the purge gas is supplied to the processing space 38 in which the substrate W is placed. The controller 6 performs control to open the valves 52e and 55e. After a predetermined period of time has elapsed, the controller 6 performs control to close the valves 52e and 55e. As a result, the purge gas stored in the storage tanks 52d and 55d is supplied into the processing space 38 of the processing container 1, and the raw material gas remaining in the processing container 1 is quickly discharged to the exhaust pipe 41, so that the interior of the processing container 1 is switched from a raw material gas atmosphere to a purge gas atmosphere in a short period of time.

In Operation S504, an oxidizing agent is supplied to the processing space 38 in which the substrate W is placed. Here, an oxygen-containing gas (O₃ gas) is supplied as the oxidizing agent. The controller 6 performs control to open the valve 54e. After a predetermined period of time has elapsed, the controller 6 performs control to close the valve 54e. As a result, the oxygen-containing gas stored in the storage tank 54d is supplied into the processing space 38 of the processing container 1, so that the raw material gas adsorbed onto the substrate W is oxidized by the oxygen-containing gas to form MgO.

In Operation S505, the purge gas is supplied to the processing space 38 in which the substrate W is placed. The controller 6 performs control to open the valves 52e and 55e. After a predetermined period of time has elapsed, the controller 6 performs control to close the valves 52e and 55e. As a result, the purge gas stored in the storage tanks 52d and 55d is supplied into the processing space 38 of the processing container 1, and the oxygen-containing gas remaining in the processing container 1 is quickly discharged to the exhaust pipe 41, so that the interior of the processing container 1 is replaced from an oxygen-containing gas atmosphere to a purge gas atmosphere in a short period of time.

When processes of Operations S502 to S505 are referred to as one cycle of an ALD process, it is determined in Operation S506 whether or not the cycle has been repeated a predetermined number of times. When the cycle has not been repeated the predetermined number of times (“NO” in Operation S506), processing of the controller 6 returns to Operation S502. When it is determined that the cycle has been repeated the predetermined number of times (“YES” in Operation S506), the film forming processing by the controller 6 ends.

In this way, by repeating the cycle of the ALD process (Operation S502 to Operation S505) the predetermined number of times, an MgO film (the protective film 320) having a predetermined film thickness is formed on the substrate W. In addition, by forming the MgO film by the ALD process, the film formation may be performed with good coverage.

Thereafter, the substrate W is taken out of the processing container 1 in a reverse order of loading the substrate W into the processing container 1.

In the above example, while the case in which the purge gas stored in the storage tank 52d and 55d is supplied into the processing container 1 to purge the interior of the processing container 1 has been described in Operations S503 and S505, the present disclosure is not limited thereto. For example, the interior of the processing container 1 may be purged by the carrier gas supplied into the processing container 1 from the carrier gas sources 53a and 56a.

In addition, while the case in which the oxygen-containing gas is supplied to the processing space 38 in which the substrate W is placed has been described in Operation S504, the present disclosure is not limited thereto. The film formation apparatus 110 may be provided with a remote plasma apparatus (not shown) that generates remote plasma and supplies oxygen radicals into the processing space 38 of the processing container 1. In this case, in Operation S504, a configuration may be provided in which the oxygen radicals are supplied from the remote plasma apparatus (not shown) to the processing space 38 in which the substrate W is placed. Thus, the raw material gas adsorbed onto the substrate W is oxidized by the oxygen radicals to form MgO. In addition, the oxygen radicals are an example of the oxidizing agent that oxidizes the organometallic gas containing magnesium (Mg) adsorbed onto the substrate W.

Referring back to FIG. 2 and FIGS. 3A to 3C, in Operation S203, the dry etching process is performed on the substrate W in which a stacked structure of the base film 310 and the protective film 320 formed thereon. Here, the dry etching process is performed on the substrate W by the dry etching apparatus 120. The substrate W has a first portion in which the stacked structure of the base film 310 and the protective film 320 covering the base film 310 is formed, and a second portion having an etching target film (e.g., a SiO₂ film), a shape of which is processed by the dry etching process. In this case, the shape of the etching target film of the second portion is processed by performing the dry etching process on the substrate W.

Here, the protective film 320 has dry etching resistance and protects the base film 310 from the dry etching process in Operation S203. In addition, after the dry etching process, the protective film 320 remains on the base film 310.

In Operation S204, DIW process (cleaning processing using pure water) is performed on the substrate W in which the stacked structure of the base film 310 and the protective film 320 is formed.

An example of the substrate W after the DIW process will now be described with reference to FIG. 3C. FIG. 3C is an example of a schematic cross-sectional diagram of the substrate W after the processing in Operation S204.

Here, since the protective film 320 is soluble in water (DIW), the protective film 320 covering the base film 310 is removed.

In this way, the protective film 320 may be desirably removed using water (DIW). Here, in a configuration in which the protective film is removed using a chemical solution such as acid, there is a concern that the base film may be corroded by the chemical solution. In this regard, in the present embodiment, since the protective film 320 may be removed using water (DIW), the corrosion of the base film 310 may be prevented.

While the MgO film of the present embodiment has been described as being used as the protective film 320 that protects the base film 310 during the dry etching process, the present disclosure is not limited thereto. The MgO film of the present embodiment may also be used as an etch stop film.

That is, in Operation S202, after forming the MgO film (the protective film 320) on the base film 310, the SiO₂ film (etching target film in the dry etching process) is formed on the MgO film. Thereafter, in Operation S204, the dry etching process is performed on the substrate W to dry-etch the SiO₂ film. In this case, the MgO film may be used as the etch stop film.

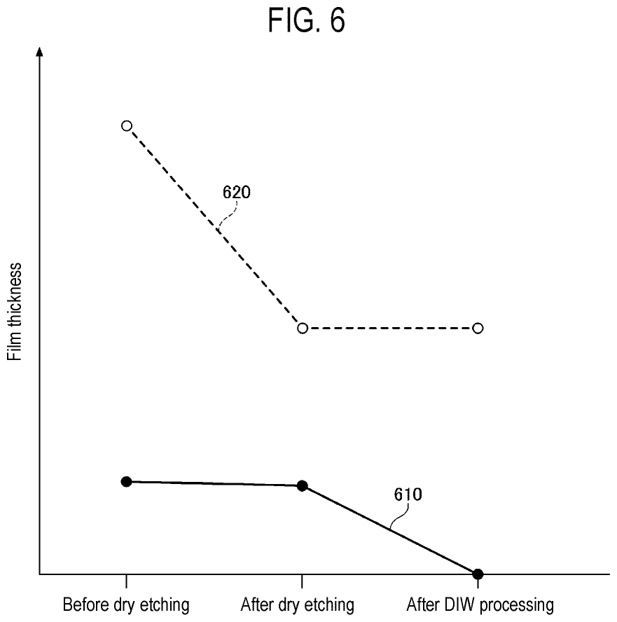

Next, characteristics of the MgO film of the present embodiment will be described with reference to FIG. 6. FIG. 6 is a graph illustrating an example of film thickness before and after the dry etching process and after the DIW process. Here, the MgO film (the protective film 320) of the present embodiment and the silicon oxide film (SiO₂) film as the etching target film in the dry etching process are compared with each other. Specifically, the dry etching process and the DIW process were performed on each of a substrate having a single film of the MgO film (corresponding to the protective film 320) formed thereon and a substrate having a single film of the SiO₂ film (corresponding to the etching target film on which the MgO film has not been provided) thereon, and film thicknesses before and after the dry etching process and after the DIW process were measured. In addition, a change in the film thickness of the MgO film of the present embodiment is indicated by reference numeral 610. Further, a change in the film thickness of the SiO₂ film is indicated by reference numeral 620.

In this example, the MgO film of the present embodiment was formed using bis(ethylcyclopentadienyl)magnesium as the raw material gas, using the O₃ gas containing the O₂ gas as the oxygen-containing gas, at the film formation temperature of 250 degrees C.

In addition, the dry etching process was performed under conditions for etching the silicon oxide film (SiO₂ film). Specifically, the substrate W was subjected to plasma etching using an etching gas containing a C₄F₈ gas.

As illustrated by comparing the film thickness change 610 of the MgO film of the present embodiment and the film thickness change 620 of the SiO₂ film before and after the dry etching process, the MgO film of the present embodiment has higher etching resistance than the silicon oxide film (SiO₂ film).

The film thickness of the SiO₂ film indicated by reference numeral 620 did not show any change after the dry etching process and after the DIW process. In contrast, the film thickness of the MgO film indicated by reference numeral 610 was reduced. That is, as illustrated after the DIW process, the MgO film of the present embodiment is soluble in water (DIW) and may be removed using water (DIW).

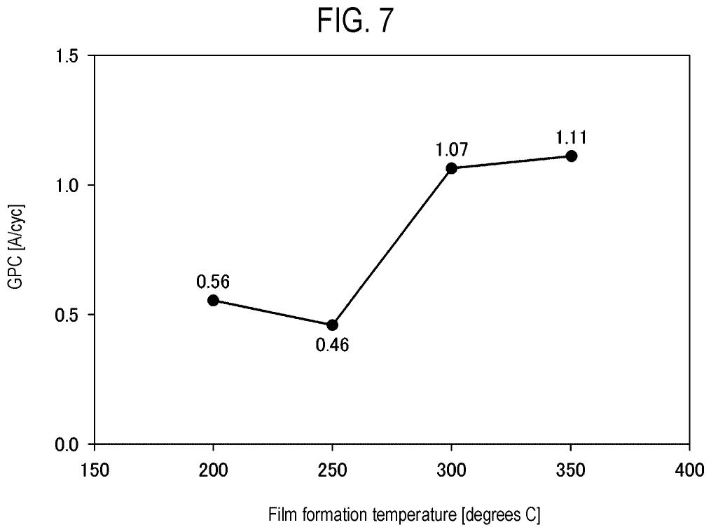

Next, a relationship between the film formation temperature and characteristics of the MgO film will be described with reference to FIGS. 7 to 10.

FIG. 7 is an example of a graph illustrating a relationship between the film formation temperature and growth per cycle (GPC) of the ALD process of the MgO film of the present embodiment. The horizontal axis represents the film formation temperature, and the vertical axis represents GPC.

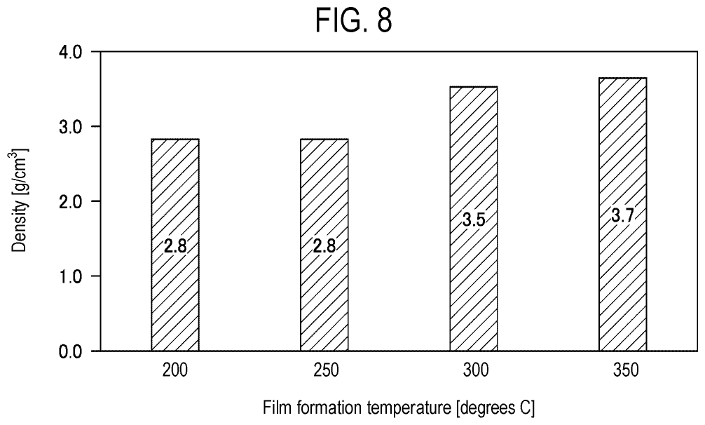

FIG. 8 is an example of a graph illustrating a relationship between the film formation temperature and a density of the MgO film of the present embodiment. The horizontal axis represents the film formation temperature, and the vertical axis represents the density of the MgO film.

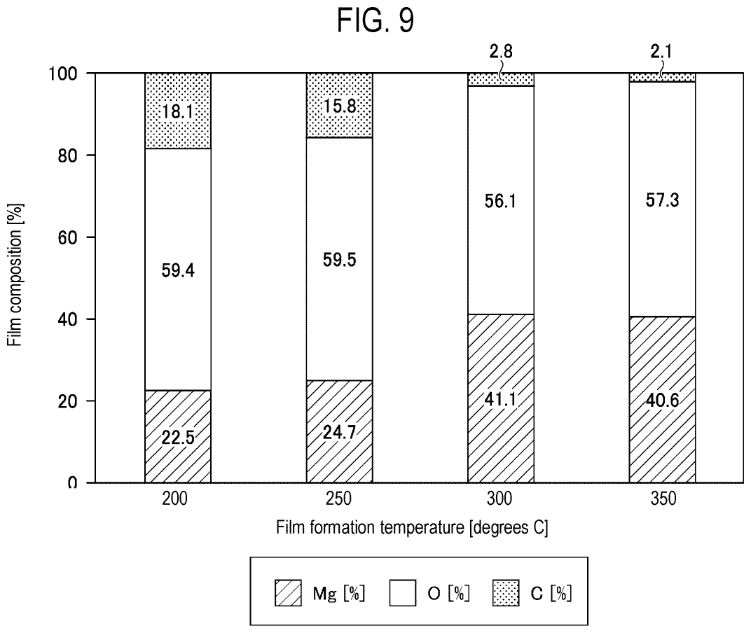

FIG. 9 is an example of a graph illustrating a relationship between the film formation temperature and a film composition of the MgO film of the present embodiment. The horizontal axis represents the film formation temperature, and the vertical axis represents the film composition. Here, an elemental composition of the MgO film was measured by energy dispersive X-ray spectroscopy (EDX), and composition ratios of magnesium (Mg), oxygen (O), and carbon (C) in the MgO film was detected.

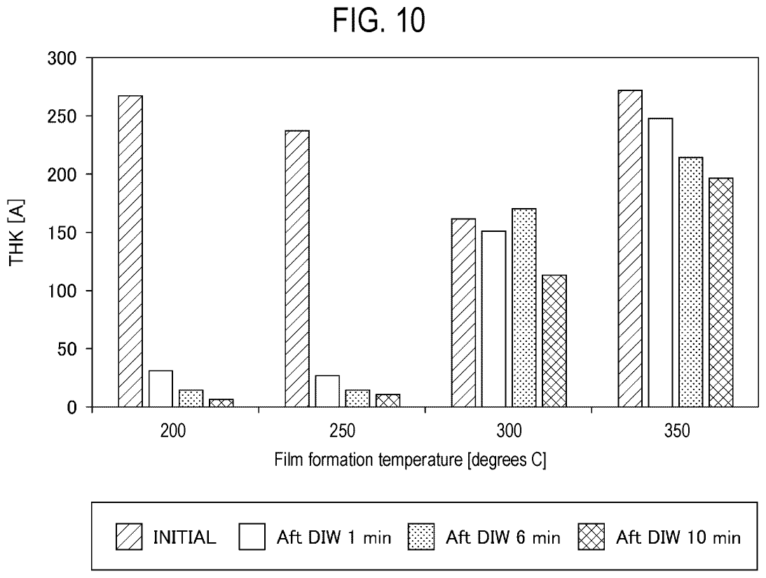

FIG. 10 is an example of a graph illustrating a relationship between the film formation temperature and the film thickness of the MgO film of the present embodiment. Here, “INITIAL” indicates the film thickness of the MgO film before the DIW process. “Aft DIW 1 min” indicates the film thickness of the MgO film after the DIW process is performed on the substrate W for 1 minute. “Aft DIW 6 min” indicates the film thickness of the MgO film after the DIW process is performed on the substrate W for 6 minutes. “Aft DIW 10 min” indicates the film thickness of the MgO film after the DIW process is performed on the substrate W for 10 minutes.

As illustrated in FIG. 7, GPC of the MgO film having a film formation temperature of 250 degrees C. or lower is lower than that of the MgO film having a film formation temperature of 300 degrees C. or higher.

In addition, as illustrated in FIG. 8, the film density of the MgO film having the film formation temperature of 250 degrees C. or lower is lower than that of the MgO film having the film formation temperature of 300 degrees C. or higher.

In addition, as illustrated in FIG. 9, the ratio of carbon (C) in the MgO film having the film formation temperature of 250 degrees C. or lower is higher than that in the MgO film having the film formation temperature of 300 degrees C. or higher.

As illustrated in FIG. 10, the MgO film having the film formation temperature of 250 degrees C. or lower may be desirably removed by the DIW process, compared to the MgO film having the film formation temperature of 300 degrees C. or higher.

As described above, as illustrated in FIGS. 7 to 9, the MgO film having the film formation temperature of 250 degrees C. or lower and the MgO film having the film formation temperature of 300 degrees C. or higher have different film characteristics (GPC, film density, and composition ratio). These differences show, as illustrated in FIG. 10, that the MgO film having the film formation temperature of 250 degrees C. or lower may be desirably removed by the DIW process.

In addition, as illustrated by comparing FIGS. 8 and 10, the density of the MgO film (the protective film 320) is desirably 2.8 [g/cm³] or lower. Thus, it is possible to obtain the MgO film (the protective film 320) that may be desirably removed by the DIW process.

In addition, as illustrated by comparing FIGS. 9 and 10, in the composition ratios of magnesium (Mg), oxygen (O), and carbon (C) in the MgO film (the protective film 320), it is desirable that the composition ratio of carbon (C) be 15[%] or more. Accordingly, the MgO film (the protective film 320) may be desirably removed by the DIW process.

According to one aspect of the present disclosure, it is possible to provide a substrate processing method and a substrate processing system which form a protective film that is likely to be removed, and the protective film.

As described above, while the method of forming the protective film 320 (the MgO film) and the method of removing the protective film 320 (the MgO film) by the substrate processing system 100 have been described, the present disclosure is not limited to the above-described embodiments and various modifications and improvements are possible within the scope of the gist of the present disclosure described in the claims.

What is claimed is:

1. A substrate processing method, comprising:
preparing a substrate having a base film formed thereon;
forming a protective film on the base film;
performing a dry etching process on the substrate in which a stacked structure of the base film and the protective film is formed; and
removing the protective film from the substrate in which the stacked structure of the base film and the protective film is formed,
wherein the forming the protective film on the base film includes forming an MgO film as the protective film by repeating supplying an organometallic gas containing magnesium (Mg) to the substrate and supplying an oxidizing agent to the substrate at a film formation temperature of 250 degrees C. or lower.

2. The substrate processing method of claim 1, wherein the removing the protective film includes supplying water to the substrate to dissolve the protective film in water and remove the protective film.

3. The substrate processing method of claim 2, wherein the organometallic gas containing Mg is any one selected from a group consisting of bis(cyclopentadienyl)magnesium, bis(methylcyclopentadienyl)magnesium, bis(ethylcyclopentadienyl)magnesium, bis(pentamethylcyclopentadienyl)magnesium, ethylbutylmagnesium, dibutylmagnesium, and bis(diisopropylamino)magnesium.

4. The substrate processing method of claim 2, wherein the oxidizing agent is any one selected from a group consisting of an O₃ gas, a mixed gas of an O₂ gas and the O₃ gas, and oxygen radicals.

5. The substrate processing method of claim 2, wherein the performing the dry etching on the substrate includes processing a shape of an etching target film formed on the substrate.

6. The substrate processing method of claim 5, wherein the protective film has higher etching resistance than the etching target film.

7. The substrate processing method of claim 6, wherein the etching target film is a silicon oxide film.

8. The substrate processing method of claim 7, wherein, in the performing the dry etching on the substrate, a CF-based gas is used as an etching gas.

9. The substrate processing method of claim 2, wherein a density of the protective film formed in the forming the protective film is 2.8 [g/cm³] or less.

10. The substrate processing method of claim 2, wherein, in composition ratios of magnesium, oxygen, and carbon in the protective film formed in the forming the protective film, a composition ratio of the carbon is 15[%] or more.

11. A substrate processing system, comprising:
a film formation apparatus configured to form a protective film by alternately supplying an organometallic gas containing magnesium (Mg) and an oxidizing agent at a film forming temperature of 250 degrees C. or lower to a substrate having a base film formed thereon;
a dry etching apparatus configured to perform a dry etching process on the substrate in which a stacked structure of the base film and the protective film is formed; and
a protective film removal apparatus configured to remove the protective film from the substrate in which the stacked structure of the base film and the protective film is formed.

12. The substrate processing system of claim 11, wherein the organometallic gas containing Mg is any one selected from a group consisting of bis(cyclopentadienyl)magnesium, bis(methylcyclopentadienyl)magnesium, bis(ethylcyclopentadienyl)magnesium, bis(pentamethylcyclopentadienyl)magnesium, ethylbutylmagnesium, dibutylmagnesium, and bis(diisopropylamino)magnesium.

13. The substrate processing system of claim 11, wherein the oxidizing agent is any one selected from a group consisting of an O₃ gas, a mixed gas of an O₂ gas and the O₃ gas, and oxygen radicals.

14. A protective film which covers a base film in a substrate on which the base film is formed,
wherein the protective film has higher etching resistance than a silicon oxide film during a dry etching process on the silicon oxide film, and is soluble in water.
